(19) United States
(12) Patent Application Publication
(10) Pub. No.: US 2011/0053094 A1
(43) Pub. Date: Mar. 3, 2011

(54) METHOD FOR FABRICATING ROLLER MOLD FOR NANOIMPRINTING

(75) Inventors: Chin-Tien Yang, Taipei County (TW); Chung-Ta Cheng, Taipei County (TW); Jung-Po Chen, Nantou County (TW); Ming-Fang Hsu, Taipei County (TW); Chun-Chieh Huang, Hsinchu City (TW); Jau-Jiu Ju, Hsinchu County (TW); Der-Ray Huang, Hsinchu City (TW)

(73) Assignee: INDUSTRIAL TECHNLOGY RESEARCH INSTITUTE, Hsinchu (TW)

(21) Appl. No.: 12/651,379

(22) Filed: Dec. 31, 2009

(30) Foreign Application Priority Data
Sep. 3, 2009 (TW) TW098129692

(51) Int. Cl. G03F 7/20

(52) U.S. Cl. 430/320

(57) ABSTRACT

A method for fabricating a roller mold is provided, including providing a roller substrate, wherein the roller substrate is a cylinder and has a curved surface. An inorganic resist layer is formed over the curved surface of the roller substrate. A laser exposure device is provided for irradiating the inorganic resist layer with a focused laser, causing phase change of the inorganic resist layer at exposed regions. The inorganic resist layer in the exposed regions is removed to form a nano-pattern over the roller substrate.

### CROSS REFERENCE TO RELATED APPLICATIONS

This Application claims priority of Taiwan Patent Application No. 98129692, filed on Sep. 3, 2009, the entirety of which is incorporated by reference herein.

### BACKGROUND

1. Technical Field

The disclosure relates to fabrication of an imprint mold for a nano-imprinting process, and more particularly, to methods of fabricating a roller imprint mold having nano-patterns formed thereover for a nano-imprinting process.

2. Description of the Related Art

With the rapid development of 3C science and technology, it is necessary for semiconductor process and information recording media process to reduce line width or the size of recording pit, so as to improve the operation speed and the recording density. Taking optical disc storage as an example, the length of the minimum recording pit of DVD discs is approximately 400 nm, and the length of the minimum recording pit of the next generation optical disc is approximately 170 nm. The line width of semiconductor process is reduced from several hundreds of nanometers to several tens of nanometers.

Therefore, in order to fabricate extremely fine line widths or recording pits, nano-processing techniques such as nanoimprint lithography (NIL) have been developed to form nano-dimensional patterns. During fabrication of an imprint mold, nano-dimensional patterns are formed on a plane mold made of organic resist materials by an electron-beam (E-beam) lithography process. However, fabrication of nano-dimensional patterns by E-beam lithography requires high equipment costs and long lithography process times. Thus, it is not feasible to use the method to fabricate large-area nano-dimensional patterns over a plane mold.

Nevertheless, a roll-to-roll method has been developed, wherein a nano-dimensional pattern formed by an E-beam lithography process is first imprinted on several flexible metal substrates. The flexible metal substrates are then attached to a roller to form a roller mold. The obtained roller mold could be applied to imprint nano-dimensional patterns on a large area surface by the roll-to-roll method. However, since the flexible metal substrates attached to the roller mold are respectively formed by imprinting method, it is difficult to precisely perform connection and alignment of the nano-dimensional patterns formed on various flexible metal substrates. In addition, an undesired seam may be formed between the flexible metal substrates, such that the nano-dimensional patterns for imprinting may not be completely provided at curved surfaces of the roller mold. Moreover, the flexible metal substrates have hardness issues such that the nano-dimensional patterns formed thereon may be easily damaged due to wear-and-tear, thereby affecting reliability and lifetime of the roller mold.

Taiwan Patent No. I305753 discloses a method for fabricating a roller mold by using an imprint roller to compress a plane mold so that patterns formed on the plane mold can be imprinted to a heated thermal imprinting material layer formed on a curved surface of a body structure having a cylinder shape, thereby forming the roller mold.

### BRIEF SUMMARY OF THE DISCLOSURE

An exemplary method for fabricating a roller mold comprises providing a roller substrate, wherein the roller substrate is a cylinder and has a curved surface. An inorganic resist layer is formed over the curved surface of the roller substrate. A laser exposure device is provided for radiating the inorganic resist layer with a focused laser and causing phase change of the inorganic resist layer at exposed regions. The inorganic resist layer in the exposed regions is removed to form a nano-pattern over the roller substrate.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1A to 1C are cross sections showing a method for fabricating a roller mold according to an embodiment of the disclosure.

FIGS. 1D to 1E are cross sections showing a method for fabricating a roller mold according to another embodiment of the disclosure.

FIGS. 2A to 2D are cross sections showing a method for fabricating a roller mold according to yet another embodiment of the disclosure.

FIGS. 3A to 3C are cross sections showing a method for fabricating a roller mold according to another embodiment of the disclosure.

### DETAILED DESCRIPTION OF THE DISCLOSURE

The following description is one of the embodiments for carrying out the disclosure. This description is made for the purpose of illustrating the general principles of the disclosure and should not be taken in a limiting sense. The scope of the disclosure is determined by reference to the appended claims.

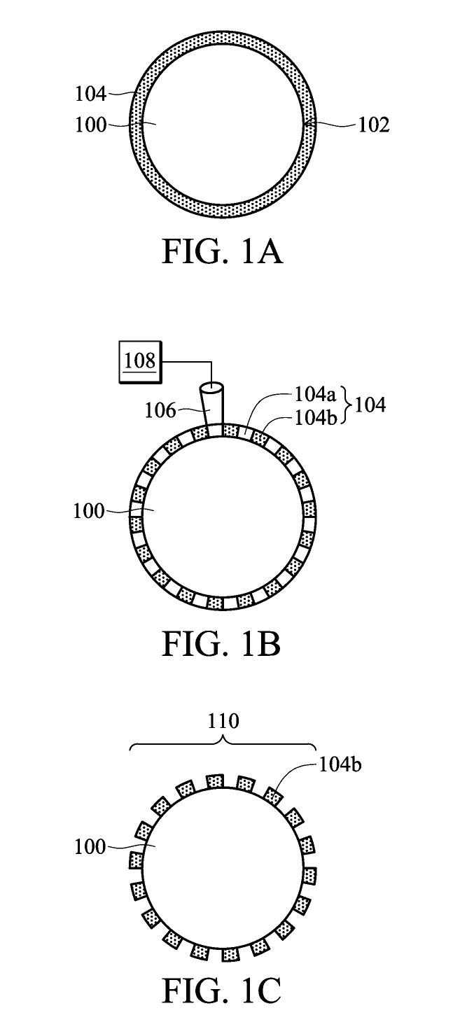

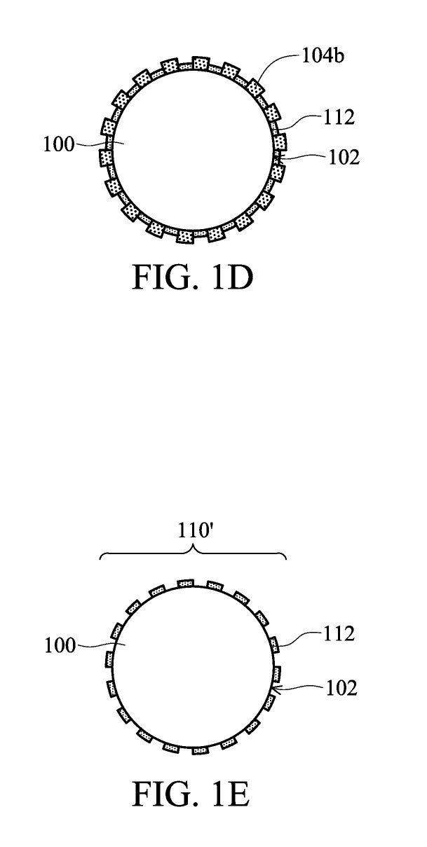

FIGS. 1A to 1C are cross sections showing an exemplary method for fabricating a roller mold.

In FIG. 1A, a roller substrate 100 of a cylinder is provided. The roller substrate 100 can be made by, for example, semiconductor materials, glass materials, plastic materials or metal materials. In one embodiment, the semiconductor materials comprise silicon. The roller substrate 100 of a cylinder has a curved surface 102. A layer of inorganic resist layer 104 is formed on the roller substrate 100 with a thickness of 10˜400 nm, or of 100˜300 nm. The inorganic resist layer 104 may comprise materials such as an incomplete oxide of a phase-change material, an incomplete oxide of a transition metal, metallic glass or ZnS—SiO₂. The so-called “incomplete oxide” means that the oxygen content of the inorganic resist material is lower than the stoichiometric oxygen content of the complete oxide of the phase-change material or the transition metal. In one embodiment, the inorganic resist layer 104 comprises an incomplete oxide of a phase-change material having a general formula A₁₋ₓOₓ, wherein A represents a phase-change material, and x is between 5 at. % and 65 at. %. The phase-change material can be, for example, an alloy selected from a group consisting of Se, Te, Sb, As, Sn, Ge, or In, such as, Ge—Sb—Te, Ge—Sb—Sn, or In—Ge—Sb—Te alloy. Taking Ge—Sb—Sn alloy as an example, when the phase-change material is expressed as a general formula of GeₐSb_{b}Sn_{1-a-b}, a is approximately 5-15 at. %, b is approximately 10-50 at. %. In another embodiment, the inorganic resist layer 104 comprises an incomplete oxide of a transition metal having a general formula B₁₋ₓOₓ, wherein A represents transition metal, and x is a non-zero value between 0 at. % and 75 at. %. In this embodiment, the inorganic resist material comprises a transition metal such as Ti, V, Cr, Mn, Fe, Nb, Cu, Ni, Co, Mo, Ta, W, Zr, Ru or Ag. In another embodiment, the inorganic resist layer 104 comprises metallic glass materials such as Mg-based metallic glass materials. The method of forming the inorganic resist layer 104 with an incomplete oxide of a phase-change material, an incomplete oxide of a transition metal, and ZnS—SiO₂ can be, for example, oxygen reactive sputtering. The method for coating the inorganic resist layer 104 with metallic glass materials can be, for example, reactive sputtering.

In FIG. 1B, the inorganic resist layer 104 is subsequently irradiated by a focused laser 106 generated by a set of laser exposure device 108, so that the exposed regions of the inorganic resist layer transit from an initial state 104b to a phase transition state 104a. The laser exposure device 108 can be an exposure device applied in a lithography process or an optical laser direct writing device used in media drivers such as CD-ROM or DVD-ROM, so that no additional equipment costs are required. If an inorganic resist layer 104 has preferred absorption in the red band, the blue band in the visible band, or the UV-band, lasers of various wavelengths can be used as the exposure sources. Phase change of the inorganic resist layer 104 is performed by adjusting the amount of power and the process time of the focused laser 106 during the exposure. On the other hand, the feature size of the subsequently formed nano-patterns can be controlled by adjusting the amount of power and process time of the focused laser 106. Furthermore, the oxygen content of the oxide layer of the phase-change material can also be controlled by adjusting the flow ratios of Ar and O₂ during the sputtering process.

In FIG. 1C, portions of the inorganic resist layer 104 transited to the phase transition state (see 104a in FIG. 1B) are next removed, so as to from a nano-pattern 110 on the inorganic resist layer 104, in which the nano-pattern 110 can be a line pattern or a recording pit. The portions of the inorganic resist layer 104 transited to the phase transition state 104a can be removed by, for example, dissolving the inorganic resist layer of the phase transition state 104a with an alkali solution, in which the alkali solution is, for example, a KOH or NaOH solution.

Thus, substantially completing fabrication of a roller mold having the nano-pattern 110 as shown in FIG. 1C. The roller substrate 100 having the nano-pattern 110 can be horizontally mounted to an imprint carrier (not shown) to perform a roll-to-roll imprinting process of the nano-pattern 110. In this embodiment, since the nano-pattern 110 disposed on the roller mold can be fabricated by a direct-writing exposure source, for example, a conventional lithography process or a laser beam of an optical device in a media driver, the fabrication of the roller mold allows fast fabrication time and low cost. Additionally, due to precise alignment, a highly integrated nano-pattern can be formed on the curved surface of the roller mold. Thus, additional imprinting devices such as a plane mold for fabricating the nano-pattern is not required, as the entire curved surface of the roller mold is fully utilized for forming the required nano-pattern. In addition, since materials of the inorganic resist layer have mechanic strength and are not easily damaged due to wear-and-tear of the roller mold, the roller mold fabricated by the above exemplary method can be widely applied in the nano-imprinting process for fabricating semiconductor devices, recording media, magnetic elements and displays of large areas.

FIGS. 1D to 1E are cross sections showing another exemplary method for fabricating a roller mold.

Referring to FIG. 1D, after the steps in FIGS. 1A to 1C, a selective deposition process (not shown) such as an electroforming process is performed on the roller mold, which is shown in FIG. 1C, and thereby form a metal layer 112 on the curved surface 102 of the roller substrate 100 covered by the initial state 104b of the a nano-patterned inorganic resist layer. Materials of the metal layer 112 can be, for example, selected from a group consisting of Ni, W, and an alloy thereof.

In FIG. 1E, the initial state 104b of the inorganic resist layer 104 is next removed to form a nano-pattern 110′ made of the metal layer 112. Herein, the nano-pattern 110′ is a reversed pattern of the nano-pattern 110 illustrated in FIG. 1C and the nano-pattern 110′ can be a line pattern or a recording pit. The initial state 104b of the inorganic resist layer can be removed by, for example, dissolving the initial state 104a of the inorganic resist layer with an aqueous solution such as KOH, HNO₃ or HF solution.

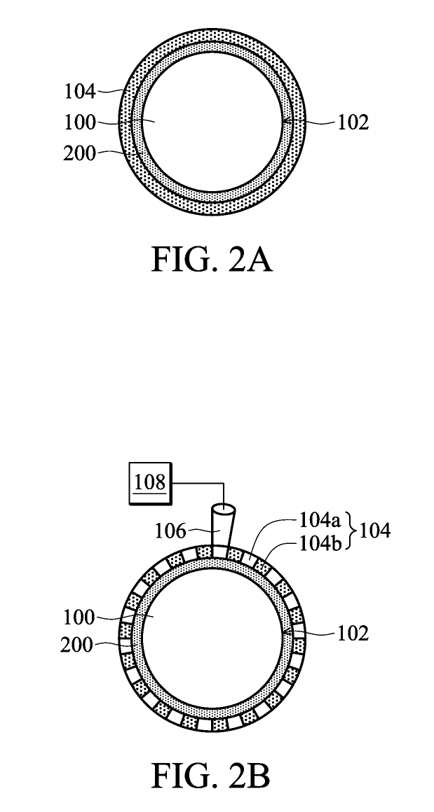

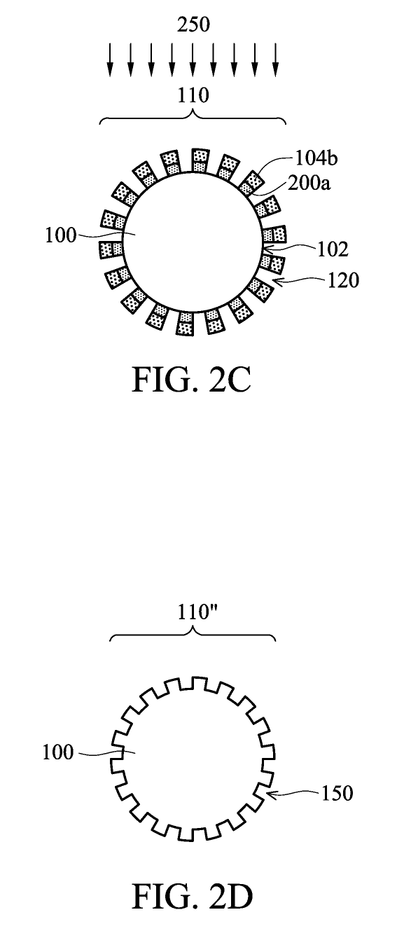

FIGS. 2A to 2D are cross sections of yet another exemplary method for fabricating a roller mold, in which the same reference numerals indicate the same components shown in previous exemplary methods.

In FIG. 2A, an intermediate layer 200 is first formed on the curved surface 102 of the roller substrate 100, and the inorganic resist layer 104 is then formed on the intermediate layer 200. The intermediate layer 200 can be a thermal barrier layer that can reduce the heat dissipation speed of the film and improve the exposure sensitivity or an etching stop layer. Also, the intermediate layer 200 may comprise materials such as Al₂O₃, AlN, SiC, SiO₂, Si₃N₄, ZnS—SiO₂, or organic polymer materials. A thickness of the intermediate layer 200 can be adjusted according to design requirements for forming the nano-patterns.

In FIG. 2B, the inorganic resist layer 104 is then irradiated with a focused laser 106 by using a laser exposure device 108, so that exposed regions of the inorganic resist layer transit from an initial state 104b to a phase transition state 104a (as shown in FIG. 2B).

In FIG. 2C, portions of the inorganic resist layer being transited to the phase transition state 104a are next removed to the intermediate layer 200 and thereby form a nano-pattern 110 having a plurality of recesses 120 therein. Next, a dry etching process 250 is performed to etch the intermediate layer 200 and the roller substrate 100 exposed by the recesses 120, using the initial state 104b of the inorganic resist layer as an etching mask. The dry etching process 250 can be, for example, a reactive ion etching (RIE) or an inductive coupling plasma (ICP) etching process. The initial state 104b of the inorganic resist layer 104 and the underlying patterned intermediate layer 200a are next removed and thereby the nano-pattern 110 in FIG. 2C is transferred to the roller substrate 100 and form a transferred nano-pattern 110″, as shown in FIG. 2D. Herein, due to formation of the transferred nano-pattern 110′, a roller substrate 100 is formed with a curved surface 150 having a concave and convex structure which is different from the curved surface 102 illustrated in FIG. 2A.

Thus, a substantially completed roller mold having the transferred nano-pattern 110″ is fabricated as shown in FIG. 2D. The roller substrate 100 having the transferred nano-pattern 110″ can be horizontally mounted to an imprint carrier (not shown) to perform a roll-to-roll imprinting process of the transferred nano-pattern 110″. In this embodiment, since the transferred nano-pattern 110″ disposed on the roller mold can be fabricated by a direct-writing exposure source, for example, a conventional lithography process or a laser beam of an optical device in a media driver, the fabrication of the roller mold allows fast fabrication time and low cost. Additionally, due to precise alignment, a highly integrated nano-pattern can be formed on the curved surface of the roller mold. Thus, additional imprinting devices such as a plane mold for fabricating the nano-pattern are not required, as the entire curved surface of the roller mold is fully utilized for forming the required nano-pattern. In addition, since materials of the inorganic resist layer have mechanic strength and are not easily damaged due to wear-and-tear of the roller mold, the roller mold fabricated by the above exemplary method can be widely applied in the nano-imprinting process for fabricating semiconductor devices, recording media, magnetic elements and large-area displays.

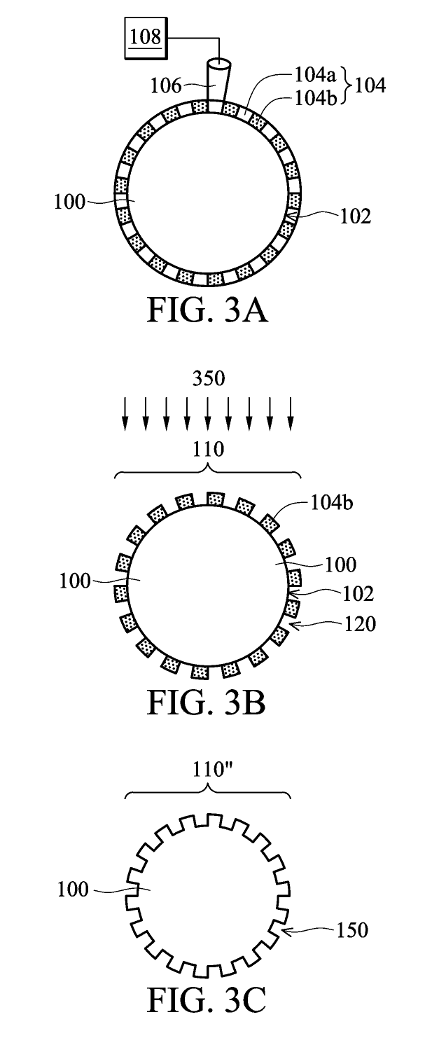

FIGS. 3A to 3D are cross sections of yet another method for fabricating a roller mold, in which the same reference numerals indicate the same components shown in previous exemplary methods.

Referring to FIG. 3A, an inorganic resist layer 104 is formed over the roller substrate 100. The inorganic resist layer 104 is next irradiated with a focused laser 106 by using a set of laser exposure device 108, so that the exposed regions of the inorganic resist layer transit from an initial state 104b to a phase transition state 104a.

In FIG. 3B, the portions of the inorganic resist film transited to the phase transition state 104a are next removed, so as to from a nano-pattern 110 having a plurality of recesses 120 in the inorganic resist layer 104. After completing the nano-pattern 110, the roller substrate 100 exposed by the recesses 120 is etched by a dry etching process 350 and the initial state 104b of the inorganic resist film act as a mask, in which the dry etching process includes an RIE or ICP etching process. The initial state 104b of the inorganic resist layer is then removed and the nano-pattern 110 shown in FIG. 3B is transformed to the roller substrate 100, thereby forming a transferred nano-pattern 110″ which is the same as the nano-pattern 110 illustrated in FIG. 3B. Herein, due to formation of the transferred nano-pattern 110″, the roller substrate 100 is now formed with a curved surface 150 having a concave and convex structure which is different from the curved surface 102 illustrated in FIG. 3A.

Thus, substantially completing fabrication of roller mold having the transferred nano-pattern 110″ as shown in FIG. 3C. The roller substrate 100 having the transferred nano-pattern 110″ can be then horizontally mounted to an imprint carrier (not shown) to perform a roll-to-roll imprinting process of the transferred nano-pattern 110″. In this embodiment, since the transferred nano-pattern 110″ disposed on the roller mold can be fabricated by a direct-writing exposure source, for example, a conventional lithography process or a laser beam of an optical device in a media driver, the fabrication of the roller mold allows fast fabrication time and low cost. Additionally, due to precise alignment, a highly integrated nano-pattern can be formed on the curved surface of the roller mold. Thus, additional imprinting devices such as a plane mold for fabricating the nano-pattern are not required, as the entire curved surface of the roller mold is fully utilized for forming the required nano-pattern. In addition, since materials of the inorganic resist layer have mechanic strength and are not easily damaged due to wear-and-tear of the roller mold, the roller mold fabricated by the above exemplary method can be widely applied in the nano-imprinting process for fabricating semiconductor devices, recording media, magnetic elements and large-area displays.

In the above exemplary methods, a lithographic process can be achieved by performing a thermally direct writing type photolithographic process to an inorganic resist and thereby dramatically reduce laser spot for exposure used therein. Therefore, a nano-pattern can be formed in a cost effective way. In addition, since the methods for fabricating a roller mold having nano-patterns thereon by a direct-writing laser exposure device are disclosed, the inorganic resist layer can be directly used as an imprint layer after direct writing and etching of the inorganic resist layer, or an imprint layer can be further formed after performing an electroforming process, thereby forming a continuous and seamless large area nano-pattern. Moreover, the inorganic resist layer in the above exemplary methods shows a predetermined mechanical strength greater than of a flexible metal substrate and an imprint layer can be further formed by an electroforming process so as to function as a contact surface of the roller mold. Moreover, while conventional organic resist layer can be uniformly formed over a roller mold, process difficulties exist due to diffraction limitations of the photolithography process. Therefore, the inorganic resist layer formed by sputtering methods as disclosed in the above exemplary methods are preferably used to solve the above conventional drawbacks of organic resist layer.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a roller mold, comprising:
providing a roller substrate, wherein the roller substrate is a cylinder and has a curved surface;
forming an inorganic resist layer over the curved surface of the roller substrate;
providing a laser exposure device to irradiate the inorganic resist layer with a focused laser and cause phase change of the inorganic resist layer at exposed regions; and
removing the inorganic resist layer in the exposed regions, forming a nano-pattern over the roller substrate.

2. The method as claimed in claim 1, wherein a width of the nano-pattern is adjusted by changing a power and a process time of the focus laser for irradiating the inorganic resist layer.

3. The method as claimed in claim 1, wherein a wavelength band of the laser exposure device comprises a visible band, or an UV-band.

4. The method as claimed in claim 1, wherein the method for removing the inorganic resist film in the exposed regions comprises dissolving the inorganic resist film in a phase change state by an alkali solution.

5. The method as claimed in claim 4, wherein the alkali solution comprises a KOH or NaOH solution.

6. The method as claimed in claim 1, wherein the roller substrate comprises silicon, glass, plastic, or metal.

7. The method as claimed in claim 1, after forming the nano-pattern, further comprising:
forming a metal layer on the curved surface of the roller substrate exposed by the nano-pattern; and
removing the nano-pattern, leaving a reversed nano-pattern on the curved surface of the roller substrate.

8. The method as claimed in claim 7, wherein the metal layer is formed by an electroforming process.

9. The method as claimed in claim 7, wherein the metal layer comprises materials selected from a group consisting of Ni, W, and an alloy thereof.

10. The method as claimed in claim 1, before forming the inorganic resist layer over the roller substrate, further comprising forming an intermediate layer over the roller substrate.

11. The method as claimed in claim 10, wherein the intermediate layer is a thermal barrier layer or an etching stop layer.

12. The method as claimed in claim 10, wherein the intermediate layer comprises Al₂O₃, AlN, SiC, SiO₂, Si₃N₄, ZnS—SiO₂, or organic polymer materials.

13. The method as claimed in claim 10, further comprising:
performing a dry etching process by using the nano-pattern as an etch mask, etching the intermediate layer and the roller substrate; and
removing the nano-pattern and the intermediate layer, leaving a transferred nano-pattern.

14. The method as claimed in claim 13, wherein the dry etching process comprises a reactive ion etching or an inductive coupling plasma etching.

15. The method as claimed in claim 1, after forming the nano-pattern, further comprising:
performing a dry etching process by using the nano-pattern as a mask, etching the roller substrate; and
removing the nano-pattern, forming a transferred nano-pattern in the roller substrate.

16. The method as claimed in claim 15, wherein the dry etching process comprises reactive ion etching (RIE) or inductive coupling plasma (ICP) etching.

17. The method as claimed in claim 1, wherein the inorganic resist layer comprises an incomplete oxide of a phase-change material, an incomplete oxide of a transition metal, metallic glass or ZnS—SiO₂.

18. The method as claimed in claim 17, wherein the incomplete oxide of a phase-change material has a general formula of A₁₋ₓOₓ, wherein A represents a phase-change material, and x is between 5 at. % and 65 at. %.

19. The method as claimed in claim 18, wherein the phase-change material is an alloy consisting of elements selected from Se, Te, Sb, As, Sn, Ge, and In.

20. The method as claimed in claim 19, wherein the phase-change material comprises Ge—Sb—Te, Ge—Sb—Sn, or In—Ge—Sb—Te alloy.

21. The method as claimed in claim 17, wherein the incomplete oxide of a transition metal has a general formula of B₁₋ₓOₓ, wherein B represents the transition metal, and x is a non-zero value between 0 at. % and 75 at. %.
